(19) United States
(12) Patent Application Publication
(10) Pub. No.: US 2011/0053335 A1
(43) Pub. Date: Mar. 3, 2011

(54) PHASE-CHANGE MEMORY DEVICE AND METHOD OF MANUFACTURING PHASE-CHANGE MEMORY DEVICE

(75) Inventor: TAKAYUKI SASAKI, TOKYO (JP)

(73) Assignee: ELPIDA MEMORY, INC., TOKYO (JP)

(21) Appl. No.: 12/862,831

(22) Filed: Aug. 25, 2010

(30) Foreign Application Priority Data
Sep. 3, 2009 (JP) 2009-203735

(51) Int. Cl. H01L 21/02

(52) U.S. Cl. 438/382; 257/E21.004

(57) ABSTRACT

A method of forming a semiconductor device includes the following processes. A heater electrode film is formed in a first inter-layer insulating film that is over a semiconductor substrate. A mask is formed over the heater electrode film. The first inter-layer insulating film is selectively removed using the mask to expose a side surface of an upper portion of the heater electrode film. The exposed side surface of the heater electrode film is subjected to an anisotropic etching process using the mask, to selectively remove the heater electrode film to form a heater electrode which is tapered to its top. The mask is removed. A phase change recording layer is formed, which contacts the top of the heater electrode.

### BACKGROUND OF THE INVENTION

1. Field of the Invention

The present invention relates to a phase-change memory device and a method of manufacturing a phase-change memory device.

Priority is claimed on Japanese Patent Application No. 2009-203735, filed Sep. 3, 2009, the content of which is incorporated herein by reference.

2. Description of the Related Art

In recent years, a phase-change memory device (PRAM) that performs recording using a phase-change recording layer has received a great deal of attention as an alternative semiconductor memory to DRAMs. The phase-change memory device (PRAM) is a semiconductor memory that performs recording using a phase-change material. For example, the phase-change memory device supplies a current to a heater electrode that is arranged below the phase-change recording layer. Supply of a current to the heater electrode will generate a heat on a contact interface between the heater electrode and the phase-change recording layer. The generated heat is used to change the phase of a phase-change material. The phase-change material forms the phase-change recording layer. In some cases, the phase change may be a change from a crystalline state to a non-crystalline state. In some cases, the phase change may be another change from the non-crystalline state to the crystalline state. The phase-change material has different electrical resistances values between in the crystalline state and in the non-crystalline state. The phase-change memory device performs memory functions using the difference of the electric resistance values.

An example of a phase-change memory device 100 according to the related art will be described with reference to FIG. 1. FIG. 1 is a fragmentary cross-sectional elevation view illustrating the phase-change memory device 100 according to the related art.

The phase-change memory device 100 according to the related art includes a MOS transistor 130, a storage element unit 131, and a ground line 105.

The MOS transistor 130 includes a first diffusion layer 102, a second diffusion layer 103, and a gate electrode 106.

A first diffusion layer 102 and a second diffusion layer 103 are formed beneath the surface of a semiconductor substrate 101. The first diffusion layer 102 is connected to a heater electrode 117, which will be described below. The second diffusion layer 103 is connected through a second contact plug 104 to a ground line 105, which will be described below. The gate electrode 106 is disposed between the first diffusion layer 102 and the second diffusion layer 103. The gate electrode 106 is connected to a word line (not shown). The MOS transistor 130 is covered by a first interlayer insulating film 111.

The storage element unit 131 includes a first contact plug 110, the heater electrode 117, a phase-change recording layer 120, and an upper electrode 121.

The first contact plug 110 is provided on the first diffusion layer 102. The first contact plug 110 is surrounded by a titanium nitride film 115 and a titanium film 116. The heater electrode 117 is connected to the first contact plug 110.

The heater electrode 117 may be made of, for example, tungsten (W). The heater electrode 117 is surrounded by a third side wall 118. The third side wall 118 may be made of, for example, silicon nitride (SiN). The third side wall 118 is surrounded by a second interlayer insulating film 112. The phase-change recording layer 120 extends over the heater electrode 117 and the second interlayer insulating film 112. The upper electrode 121 extends over the phase-change recording layer 120. The upper electrode 121 is connected to a bit line (not shown). In this way, the upper electrode 121 is electrically connected to the ground line 105, which will be described below.

The second contact plug 104 is formed on the second diffusion layer 103. The ground line 105 is formed on the second contact plug 104. The ground line 105 is surrounded by the first interlayer insulating film 111.

If the MOS transistor 130 turns on, then a current flows between the upper electrode 121 and the ground line 105, so that the heater electrode 117 generates a heat. The heat is transmitted to the phase-change recording layer 120. The phase-change recording layer 120 is changed in its phase, resulting in a change in series electrical resistance. In this case, a phase change occurs in a phase-change region 120a.

In order to efficiently heat the phase-change recording layer 120, it is effective to minimize the heating region or heating spot of the phase-change recording layer 120. When the heating spot is reduced, a concentration is caused of the current on one path.

Japanese Unexamined Patent Application, First Publication, No. JP-A-2008-066449 discloses a method of reducing the heating spot by reducing the diameter of the heater electrode 117. A method has been known which interposes a backup plug with a diameter smaller than that of the first contact plug 110 into between the heater electrode 117 and the first contact plug 110. The backup plug reduces the diameter of the heater electrode 117. A method has been known which uses a heater electrode 117 made of a high-resistance material.

Japanese Unexamined Patent Application, First Publication, No. JP-A-2003-332529 discloses that the surface of the electrode is covered with an interlayer insulating film and only a portion of the electrode comes into contact with the phase-change recording layer 120.

Japanese Unexamined Patent Application, First Publication, No. JP-A-2008-071797 discloses a method in which a side wall is formed of an insulating film with oxidation resistance in order to prevent the oxidation of the heater electrode 117 and the periphery thereof due to the generation of heat.

The above-described related arts are also disclosed in Japanese Unexamined Patent Applications, First Publications, Nos. JP-A-2006-287222, JP-A-2007-80978, JP-A-2008-159612, JP-A-2008-71384, JP-A-2008-85204, JP-A-2008-130804,

JP-A-2008-60541, JP-A-2006-237615, JP-A-2006-196900, JP-A-2005-244235, JP-A-2005-100617, JP-A-2006-182781, JP-A-2006-179778, and JP-A-2008-519460.

In order to further improve the capacity of the PRAM (phase-change memory device 100), it is effective to reduce the contact area between the heater electrode 117 and the phase-change recording layer 120. The reason is that, if the heating region (heating spot) of the phase-change recording layer 120 is minimized, the current path is concentrated onto a contact portion between the heater electrode 117 and the phase-change recording layer 120. This makes it possible to heat (change the phase of) the phase-change recording layer 120 with low power.

### SUMMARY

In one embodiment, a method of forming a semiconductor device may include, but is not limited to, the following processes. A heater electrode film is formed in a first inter-layer insulating film that is over a semiconductor substrate. A mask is formed over the heater electrode film. The first inter-layer insulating film is selectively removed using the mask to expose a side surface of an upper portion of the heater electrode film. The exposed side surface of the heater electrode film is subjected to an anisotropic etching process using the mask, to selectively remove the heater electrode film to form a heater electrode which is tapered to its top. The mask is removed. A phase change recording layer is formed, which contacts the top of the heater electrode.

In another embodiment, a method of forming a semiconductor device may include, but is not limited to, the following processes. A heater electrode film and a monitoring pattern are formed in a first inter-layer insulating film over a semiconductor substrate. A mask is formed, which covers the heater electrode film without covering the monitoring pattern. The first inter-layer insulating film is selectively removed using the mask to expose the monitoring pattern and a side surface of an upper portion of the heater electrode film. The monitoring pattern and the exposed side surface of the heater electrode film are subjected to an anisotropic etching process using the mask, to selectively remove the heater electrode film until the monitoring pattern is completely removed, to form a heater electrode which is tapered to its top. The mask is removed. A phase change recording layer is formed, which contacts the top of the heater electrode.

n still another embodiment, a method of forming a semiconductor device may include, but is not limited to, the following processes. A first inter-layer insulating layer is formed over a semiconductor substrate. A first opening is formed in the first inter-layer insulating layer. A contact plug is formed in the first opening. A second inter-layer insulating layer is formed over the contact plug and the first inter-layer insulating layer. A second opening is formed in the second insulating layer. The second opening is positioned over the contact plug. A first heater electrode layer is formed in the second hole. A third insulating layer is formed over the second insulating layer and the first heater electrode layer. A third opening is formed in the third insulating layer. The third opening is positioned over the first heater electrode layer. A second heater electrode layer is formed in the third hole. The second heater electrode layer is on the first heater electrode layer. The first and second heater electrode layers form the heater electrode film. A mask is formed over the heater electrode film. The third inter-layer insulating film may be selectively removed by using the mask to expose the side surface of the second heater electrode layer. The exposed side surface of the heater electrode film is subjected to an anisotropic etching process using the mask, to selectively remove the heater electrode film to form a heater electrode which is tapered to its top. The mask is removed. A fourth inter-layer insulating film is formed which covers the heater electrode. A phase change recording layer is formed over the fourth inter-layer insulating film. The phase change recording layer contacts the top of the heater electrode.

In an additional embodiment, a semiconductor device may include, but is not limited to, a contact plug, a heater electrode, and a phase change recording layer. The contact plug is disposed over a semiconductor substrate. A heater electrode has a bottom portion which covers an upper surface of the contact plug. The heater electrode is tapered to its top portion. The phase change recording layer contacting the top portion of the heater electrode.

In a further embodiment, a semiconductor device may include, but is not limited to, a contact plug, a phase change recording layer, and a heater electrode. The heater electrode has top and bottom portions. The top portion contacts the phase change recording layer. The bottom portion contacts the plug electrode. A top contact area between the top portion and the phase change recording layer is smaller than a bottom contact area between the bottom portion and the first contact plug.

In a still further embodiment, the apparatus comprises a semiconductor device may include, but is not limited to, a semiconductor substrate, a first inter-layer insulating film, a contact plug, a second inter-layer insulating film, a heater electrode, a third inter-layer insulating film, a phase change recording layer, and an upper electrode. The first inter-layer insulating film is disposed over the semiconductor substrate. The first inter-layer insulating film has a first opening. The contact plug is disposed in the first opening of the first inter-layer insulating film. The second inter-layer insulating film is disposed over the first inter-layer insulating film. The second inter-layer insulating film has a second opening. The second opening is positioned over the contact plug. The heater electrode has a bottom portion contacting an upper surface of the contact plug. The heater electrode is tapered to its top portion. The third inter-layer insulating film covers the second inter-layer insulating film. The third inter-layer insulating film covers a tapered side surface of the heater electrode. The phase change recording layer is disposed over the third inter-layer insulating film. The phase change recording layer contacts the top portion of the heater electrode. The upper electrode is disposed on the phase change recording layer.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross-sectional elevation view illustrating a phase-change memory device according to the related art;

FIG. 2 is a fragmentary cross-sectional elevation view illustrating a phase-change memory device in accordance with a first embodiment of the invention;

FIG. 3 is a fragmentary cross-sectional elevation view illustrating a phase-change memory device in a step involved in a method of forming the phase-change memory device of FIG. 2;

FIG. 4 is a fragmentary cross-sectional elevation view illustrating a phase-change memory device in a step, subsequent to the step of FIG. 3, involved in the method of forming the phase-change memory device of FIG. 2;

FIG. 5 is a fragmentary cross-sectional elevation view illustrating a phase-change memory device in a step, subsequent to the step of FIG. 4, involved in the method of forming the phase-change memory device of FIG. 2;

FIG. 6 is a fragmentary cross-sectional elevation view illustrating a phase-change memory device in a step, subsequent to the step of FIG. 5, involved in the method of forming the phase-change memory device of FIG. 2;

FIG. 7 is a fragmentary cross-sectional elevation view illustrating a phase-change memory device in a step, subsequent to the step of FIG. 6, involved in the method of forming the phase-change memory device of FIG. 2;

FIG. 8 is a fragmentary cross-sectional elevation view illustrating a phase-change memory device in a step, subsequent to the step of FIG. 7, involved in the method of forming the phase-change memory device of FIG. 2;

FIG. 9 is a fragmentary cross-sectional elevation view illustrating a phase-change memory device in a step, subsequent to the step of FIG. 8, involved in the method of forming the phase-change memory device of FIG. 2;

FIG. 10 is a fragmentary cross-sectional elevation view illustrating a phase-change memory device in a step, subsequent to the step of FIG. 9, involved in the method of forming the phase-change memory device of FIG. 2;

FIG. 11 is a fragmentary cross-sectional elevation view illustrating a phase-change memory device in a step, subsequent to the step of FIG. 10, involved in the method of forming the phase-change memory device of FIG. 2;

FIG. 12 is a fragmentary cross-sectional elevation view illustrating a phase-change memory device in a step, subsequent to the step of FIG. 11, involved in the method of forming the phase-change memory device of FIG. 2;

FIG. 13 is a fragmentary cross-sectional elevation view illustrating a phase-change memory device in a step, subsequent to the step of FIG. 12, involved in the method of forming the phase-change memory device of FIG. 2;

FIG. 14 is a fragmentary cross-sectional elevation view illustrating a phase-change memory device in a step, subsequent to the step of FIG. 13, involved in the method of forming the phase-change memory device of FIG. 2;

FIG. 15 is a fragmentary cross-sectional elevation view illustrating a phase-change memory device in a step, subsequent to the step of FIG. 14, involved in the method of forming the phase-change memory device of FIG. 2; and

FIG. 16 is a fragmentary cross-sectional elevation view illustrating a phase-change memory device in a step, subsequent to the step of FIG. 15, involved in the method of forming the phase-change memory device of FIG. 2.

### DETAILED DESCRIPTION OF THE PREFERRED EMBODIMENTS

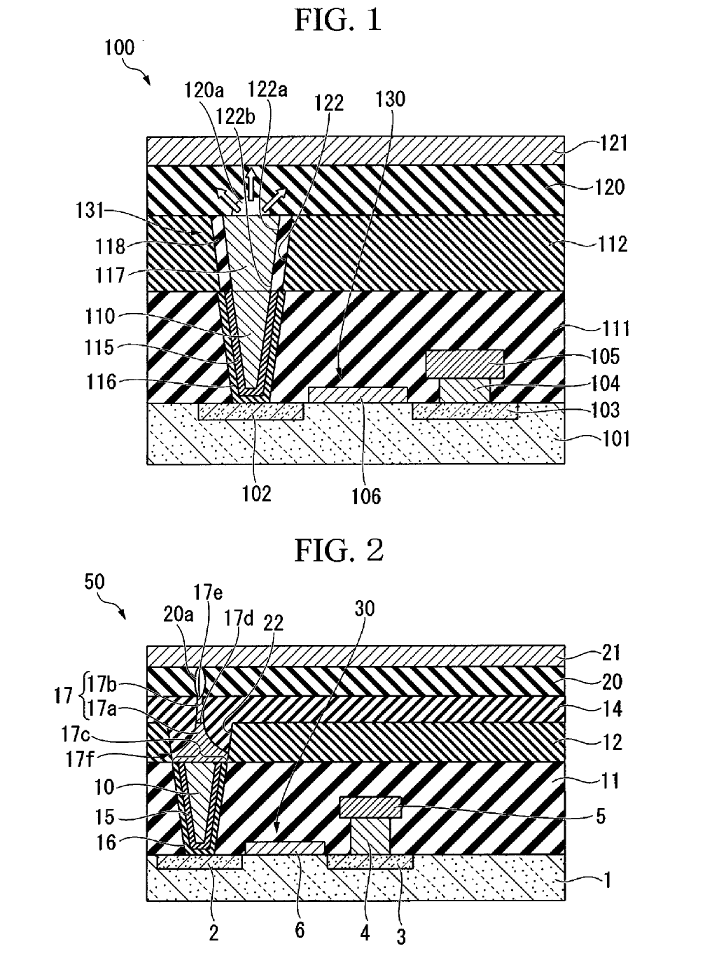

Before describing the present invention, the related art will be explained in detail with reference to FIG. 1, in order to facilitate the understanding of the present invention.

In the methods of the related art, there is a limitation in reducing the contact area between the heater electrode 117 and the phase-change recording layer 120. The heater electrode 117 is obtained by the following process. A first opening portion 122 is formed in the second interlayer insulating film 112. A third side wall 118 is formed inside the first opening portion 122. The inside of the third side wall 118 is filled with a heater electrode material. The side surface of the first opening portion 122 is such that the side surface of the first opening portion 122 is not vertical to the upper surface of the first contact plug 110 and that the diameter of the first opening portion 122 increases toward the upper side. Therefore, the diameter of the upper end of the first opening portion 122 is greater than that of the base portion of the first opening portion 122.

The third side wall 118 needs to have a thickness that does not close the base portion of the first opening portion 122. A first opening base portion 122b is formed by the formation of the third side wall 118. In order to prevent the influence of the micro-loading effect or deterioration of productivity such as missing components, it is necessary to minimize the diameter of the first opening base portion 122b.

Similarly, a first opening upper portion 122a is formed by the formation of the third side wall 118, and the opening area of the first opening upper portion 122a is the contact area between the heater electrode 117 and the phase-change recording layer 120.

Since the diameter of the first opening upper portion 122a is more than that of the first opening base portion 122b, it is difficult to reduce the first opening upper portion 122a to a desired size.

In the related art, it is difficult to reduce the diameter of the upper end portion of the heater electrode 117 to a given value or less. Therefore, even though a current flows to the heater electrode 117, the flowing of the current is diffused and it is difficult to sufficiently increase the current density of the phase-change recording layer 120. As a result, the heating efficiency of the heater electrode 117 is not sufficient and a large amount of current is required to reach a desired heating temperature. Since the contact area between the upper end portion of the heater electrode 117 and the phase-change recording layer 120 is large, the area of the phase-change region 120a is also large. Therefore, a large region of the phase-change recording layer 120 becomes the phase-change region 120a and the amount of heat required for a phase change increases. As a result, a defect is likely to occur in the heater electrode 117 or the third side wall. In addition, since a large amount of current is required, it is difficult to reduce current consumption.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method of forming a semiconductor device may include, but is not limited to, the following processes. A heater electrode film is formed in a first inter-layer insulating film that is over a semiconductor substrate. A mask is formed over the heater electrode film. The first inter-layer insulating film is selectively removed using the mask to expose a side surface of an upper portion of the heater electrode film. The exposed side surface of the heater electrode film is subjected to an anisotropic etching process using the mask, to selectively remove the heater electrode film to form a heater electrode which is tapered to its top. The mask is removed. A phase change recording layer is formed, which contacts the top of the heater electrode.

In some cases, the method of forming a semiconductor device may further include, but is not limited to, the following process. An upper electrode may further be formed on the phase change recording layer.

In some cases, the method of forming a semiconductor device may further include, but is not limited to, the following process. A second inter-layer insulating film is formed, which covers the heater electrode. The second inter-layer insulating film is formed after removing the mask and before forming the phase change recording layer on the second inter-layer insulating film.

In some cases, the heater electrode film may be formed in the first inter-layer insulating film in the processes as follows. A first insulating layer is formed over the substrate. A first opening is formed in the first insulating layer. A first heater electrode layer is formed in the first hole. A second insulating layer is formed on the first insulating layer and the first heater electrode layer. A second opening is formed in the second insulating layer. The second opening is positioned over the first heater electrode layer. A second heater electrode layer is formed in the second hole. The second heater electrode layer is on the first heater electrode layer. The first and second heater electrode layers form the heater electrode film. The first and second insulating layers form the first inter-layer insulating film.

In some cases, the mask over the heater electrode film may be formed by forming the mask on the second heater electrode layer.

In some cases, selectively removing the first inter-layer insulating film may selectively be removed by removing the second heater electrode layer to expose the side surface of the second heater electrode layer.

In some cases, subjecting the exposed side surface of the heater electrode film may be carried out by subjecting the exposed side surface of the second heater electrode layer to the anisotropic etching process using the mask, to isotropically etch the first and second heater electrode layers.

In some cases, the heater electrode film may be formed in the first inter-layer insulating film. The heater electrode film may be formed by the processes. A first inter-layer insulating layer may be formed over the substrate. A first opening may be formed in the first inter-layer insulating layer. A first heater electrode layer may be formed in the first hole. A second inter-layer insulating layer may be formed on the first inter-layer insulating layer and the first heater electrode layer. Second and third openings may be formed in the second inter-layer insulating layer. The second opening may be positioned over the first heater electrode layer. A second heater electrode layer and a monitor pattern may be formed in the second and third holes resistively. The second heater electrode layer may be on the first heater electrode layer. The first and second heater electrode layers form the heater electrode film. The first and second inter-layer insulating layers form the first inter-layer insulating film.

In some cases, the mask over the heater electrode film ay be formed by forming the mask on the second heater electrode layer.

In some cases, selectively removing the inter-layer insulating film may be carried out by removing the second heater electrode layer to expose the monitor pattern and the side surface of the second heater electrode layer.

In some cases, subjecting the exposed side surface of the heater electrode film may be carried out by subjecting the monitor pattern and the exposed side surface of the second heater electrode layer to the anisotropic etching process using the mask, to isotropically etch the first and second heater electrode layers and the monitor pattern. The anisotropic etching process is terminated when the monitor pattern is completely removed.

In some cases, the first and second heater electrode layers are isotropically etched by an etching amount that corresponds to the thickness of the monitor pattern, provided that the monitor pattern has a horizontal size that is greater than the thickness of the monitor pattern.

In some cases, the method may include, but is not limited to, forming a contact plug in a third inter-layer insulating film over the semiconductor substrate, before forming the heater electrode over the contact plug and in the first inter-layer insulating film.

In another embodiment, a method of forming a semiconductor device may include, but is not limited to, the following processes. A heater electrode film and a monitoring pattern are formed in a first inter-layer insulating film over a semiconductor substrate. A mask is formed, which covers the heater electrode film without covering the monitoring pattern. The first inter-layer insulating film is selectively removed using the mask to expose the monitoring pattern and a side surface of an upper portion of the heater electrode film. The monitoring pattern and the exposed side surface of the heater electrode film are subjected to an anisotropic etching process using the mask, to selectively remove the heater electrode film until the monitoring pattern is completely removed, to form a heater electrode which is tapered to its top. The mask is removed. A phase change recording layer is formed, which contacts the top of the heater electrode.

In some cases, the method may include, but is not limited to, the following processes. An upper electrode is formed on the phase change recording layer. A second inter-layer insulating film is formed which covers the heater electrode after removing the mask and before forming the phase change recording layer on the second inter-layer insulating film.

In some cases, the heater electrode film may be formed in the first inter-layer insulating film by the following processes. A first insulating layer is formed over the substrate. A first opening is formed in the first insulating layer. A first heater electrode layer is formed in the first hole. A second insulating layer is formed on the first insulating layer and the first heater electrode layer. A second opening is formed in the second insulating layer. The second opening is positioned over the first heater electrode layer. A second heater electrode layer is formed in the second hole. The second heater electrode layer is on the first heater electrode layer. The first and second heater electrode layers form the heater electrode film. The first and second insulating layers form the first inter-layer insulating film. The first inter-layer insulating film may be selectively removed by removing the second heater electrode layer to expose the side surface of the second heater electrode layer.

In some cases, the method may include, but is not limited to, the following processes. A contact plug is formed in a third inter-layer insulating film over the semiconductor substrate, before forming the heater electrode over the contact plug and in the first inter-layer insulating film.

In still another embodiment, a method of forming a semiconductor device may include, but is not limited to, the following processes. A first inter-layer insulating layer is formed over a semiconductor substrate. A first opening is formed in the first inter-layer insulating layer. A contact plug is formed in the first opening. A second inter-layer insulating layer is formed over the contact plug and the first inter-layer insulating layer. A second opening is formed in the second insulating layer. The second opening is positioned over the contact plug. A first heater electrode layer is formed in the second hole. A third insulating layer is formed over the second insulating layer and the first heater electrode layer. A third opening is formed in the third insulating layer. The third opening is positioned over the first heater electrode layer.

A second heater electrode layer is formed in the third hole. The second heater electrode layer is on the first heater electrode layer. The first and second heater electrode layers form the heater electrode film. A mask is formed over the heater electrode film. The third inter-layer insulating film may be selectively removed by using the mask to expose the side surface of the second heater electrode layer. The exposed side surface of the heater electrode film is subjected to an anisotropic etching process using the mask, to selectively remove the heater electrode film to form a heater electrode which is tapered to its top. The mask is removed. A fourth inter-layer insulating film is formed which covers the heater electrode. A phase change recording layer is formed over the fourth inter-layer insulating film. The phase change recording layer contacts the top of the heater electrode.

In some cases, the method may include, but is not limited to, the following process. An upper electrode is formed on the phase change recording layer.

In some cases, the method may include, but is not limited to, the following processes. A fourth opening is formed in the third insulating layer. A monitor pattern is formed in the fourth hole. The anisotropic etching process is terminated when the monitor pattern is completely removed.

In an additional embodiment, a semiconductor device may include, but is not limited to, a contact plug, a heater electrode, and a phase change recording layer. The contact plug is disposed over a semiconductor substrate. A heater electrode has a bottom portion which covers an upper surface of the contact plug. The heater electrode is tapered to its top portion. The phase change recording layer contacting the top portion of the heater electrode.

In some cases, the semiconductor device may further include, but is not limited to, an upper electrode on the phase change recording layer.

In some cases, the semiconductor device may further include, but is not limited to, a first inter-layer insulating film which covers a tapered side surface of the heater electrode.

In some cases, the semiconductor device may further include, but is not limited to, a second inter-layer insulating film surrounding the contact plug; and a third inter-layer insulating film extending over the second inter-layer. The third inter-layer insulating film has an opening that is tapered to its bottom. The opening is positioned over the contact plug. The third inter-layer insulating film is covered by the first inter-layer insulating film.

In some cases, the heater electrode may include, but is not limited to, a lower portion and an upper portion. The upper portion is provided over the lower portion. The lower portion is within the opening of the third inter-layer insulating film.

In some cases, the top of the lower portion of the heater electrode is the same level as a top surface of the third inter-layer insulating film.

In some cases, the phase change recording layer covers the first inter-layer insulating film.

In some cases, the bottom portion of the heater electrode may have a bottom contact area contacting the plug electrode. The top portion of the heater electrode may have a top contact area contacting the phase change recording layer. The top contact area is smaller than the bottom contact area.

In some cases, the heater electrode may include, but is not limited to, a lower portion and an upper portion, the lower portion contacts the contact plug, the upper portion contacts the phase change recording layer, the lower portion is higher in tapering rate than the upper portion.

In some cases, the contact plug is tapered to its bottom portion.

In some cases, the phase change recording layer comprises at least two of germanium (Ge), antimony (Sb), tellurium (Te), selenium (Se), gallium (Ga), and indium (In).

In a further embodiment, a semiconductor device may include, but is not limited to, a contact plug, a phase change recording layer, and a heater electrode. The heater electrode has top and bottom portions. The top portion contacts the phase change recording layer. The bottom portion contacts the plug electrode. A top contact area between the top portion and the phase change recording layer is smaller than a bottom contact area between the bottom portion and the first contact plug.

In some cases, the heater electrode is tapered to its top portion. The heater electrode may include, but is not limited to, a lower portion and an upper portion. The lower portion is higher in tapering rate than the upper portion.

In some cases, the contact plug is tapered to its bottom portion.

In some cases, the semiconductor device may further include, but is not limited to, an upper electrode on the phase change recording layer.

In some cases, the semiconductor device may further include, but is not limited to, a first inter-layer insulating film, a second inter-layer insulating film, and a third inter-layer insulating film. The first inter-layer insulating film covers a tapered side surface of the heater electrode. The second inter-layer insulating film surrounds the contact plug. The third inter-layer insulating film extends over the second inter-layer.

The third inter-layer insulating film has an opening that is tapered to its bottom. The opening is positioned over the contact plug. The third inter-layer insulating film is covered by the first inter-layer insulating film.

In some cases, the top of the lower portion of the heater electrode is the same level as a top surface of the third inter-layer insulating film.

In a still further embodiment, a semiconductor device may include, but is not limited to, a semiconductor substrate, a first inter-layer insulating film, a contact plug, a second inter-layer insulating film, a heater electrode, a third inter-layer insulating film, a phase change recording layer, and an upper electrode. The first inter-layer insulating film is disposed over the semiconductor substrate. The first inter-layer insulating film has a first opening. The contact plug is disposed in the first opening of the first inter-layer insulating film. The second inter-layer insulating film is disposed over the first inter-layer insulating film. The second inter-layer insulating film has a second opening. The second opening is positioned over the contact plug. The heater electrode has a bottom portion contacting an upper surface of the contact plug. The heater electrode is tapered to its top portion. The third inter-layer insulating film covers the second inter-layer insulating film. The third inter-layer insulating film covers a tapered side surface of the heater electrode. The phase change recording layer is disposed over the third inter-layer insulating film. The phase change recording layer contacts the top portion of the heater electrode. The upper electrode is disposed on the phase change recording layer.

In some cases, the heater electrode may include, but is not limited to, a lower portion and an upper portion. The upper portion is provided over the lower portion. The lower portion is within the opening of the third inter-layer insulating film. The top of the lower portion of the heater electrode is the same level as a top surface of the third inter-layer insulating film.

In some cases, the phase change recording layer may include, but is not limited to, at least two of germanium (Ge), antimony (Sb), tellurium (Te), selenium (Se), gallium (Ga), and indium (In).

In yet another embodiment, a method of forming a semiconductor device may include, but is not limited to, the following processes. An inter-layer insulating film structure is formed over a semiconductor substrate. A heater electrode film is formed in the first inter-layer insulating film. A mask is formed over the heater electrode film. The first inter-layer insulating film is selectively removed to expose an upper surface of the heater electrode film. An anisotropic etching process is carried out to selectively etch the heater electrode film to form a heater electrode. The heater electrode is tapered to its top portion. A phase change recording layer is formed which contacts the top portion of the heater electrode. A top electrode is formed on the phase change recording layer.

A second inter-layer insulating film is formed which covers the contact plug and the first inter-layer insulating film. A first opening is formed in the second inter-layer insulating film. The first opening is positioned over the contact plug, so that the contact plug is exposed. A first heater electrode film is formed in the first opening and on the contact plug. A third inter-layer insulating film is formed is formed which covers the first heater electrode film and the second inter-layer insulating film. A second opening is formed in the third inter-layer insulating film. The second opening is positioned over the first heater electrode film, so that the heater electrode film is exposed. A second heater electrode film is formed in the second opening. A hard mask is formed over the second heater electrode film. The third inter-layer insulating film is removed so that the second heater electrode film is exposed. An anisotropic etching process is carried out using the hard mask covering the second heater electrode film. The first and second heater electrode films are anisotropically etched by the anisotropic etching process, to form a heater electrode in the second opening. The heater electrode is tapered to its top.

Second and third openings are formed in the third inter-layer insulating film simultaneously. A second heater electrode film is formed in the second opening while a monitor pattern is formed in the third opening, wherein the second heater electrode film and the monitor pattern are made of the same material. A hard mask is formed over the second heater electrode film. The third inter-layer insulating film is removed so that the second heater electrode film and the monitor pattern are exposed. An anisotropic etching process is carried out using the hard mask covering the second heater electrode film. The anisotropic etching process is terminated when the monitor pattern is completely removed. The first and second heater electrode films are anisotropically etched by the anisotropic etching process, to form a heater electrode in the second opening. The heater electrode is tapered to its top.

Hereinafter, a phase-change memory device 50 according to an embodiment of the invention will be described with reference to FIG. 2. FIG. 2 is a fragmentary cross-sectional elevation view illustrating the phase-change memory device 50 according to the embodiment of the invention. In the drawings used in the following description, in some cases, a scale of each component is appropriately changed to make it easy to understand what is described. For example, materials and dimensions exemplified in the following description are just illustrative, and the invention is not necessarily limited thereto. Various modifications of the invention can be made without departing from the scope and spirit of the invention.

A phase-change memory device including the phase-change memory device 50 according to this embodiment may include, but is not limited to, a MOS transistor 30, which is a switching element, a storage element unit 31, and a ground line 5. Hereinafter, each component will be described in detail.

### MOS Transistor 30:

The MOS transistor 30 may include, but is not limited to, a first diffusion layer 2, a second diffusion layer 3, and a gate electrode 6 having the upper surfaces covered by a first interlayer insulating film 11.

### First Diffusion Layer 2 and Second Diffusion Layer 3:

The first diffusion layer 2 and the second diffusion layer 3 that diffuse impurities are formed on the upper surface of a semiconductor substrate 1 made of silicon. In this way, each of the first diffusion layer 2 and the second diffusion layer 3 performs the functions as a source region or a drain region of the MOS transistor 30.

### Gate Electrode 6:

The gate electrode 6 may include, but is not limited to, a multi-layer structure including a polycrystalline silicon film or a metal film including impurities. The gate electrode 6 is provided on the upper surface of the semiconductor substrate 1 between the first diffusion layer 2 and the second diffusion layer 3. The gate electrode 6 is connected to a word line (not shown). A current flows through the gate electrode 6, which is not shown in FIG. 2.

### Storage Element Unit 31:

The storage element unit 31 may include, but is not limited to, a first contact plug 10, a heater electrode 17, a phase-change recording layer 20, and an upper electrode 21. The side surface of the first contact plug 10 is covered with the first interlayer insulating film 11, and the heater electrode 17 is surrounded by a second interlayer insulating film 12 and a fourth interlayer insulating film 14.

### First Contact Plug 10:

For example, the first contact plug 10 is formed by depositing tungsten (W) on a barrier film (TiN/Ti), which is a laminated film of titanium (Ti) and titanium nitride (TiN). The side surface and the bottom of the first contact plug 10 are covered with a titanium nitride film 15 and a titanium film 16. The bottom of the first contact plug 10 is connected to the first diffusion layer 2. The first interlayer insulating film 11 is formed around the first contact plug 10 so as to cover the side surface of the titanium film 16 and the upper surface of the semiconductor substrate 1.

### Heater Electrode 17:

The heater electrode 17 may be made of, for example, a titanium nitride (TiN) or tungsten (W). The heater electrode 17 may include, but is not limited to, a base portion 17c that is formed so that the base portion 17c covers the upper surface of the first contact plug 10.

The heater electrode 17 may further include, but is not limited to, a first heater electrode 17a and a second heater electrode 17b, both of which are laminated in this order in the vertical direction.

The first heater electrode 17a may be provided on the first contact plug 10 and the base portion 17c covers the upper surface of the first contact plug 10. The first heater electrode 17a may have a columnar shape. The first heater electrode 17a may have a diameter reduced from the side portion 17f to a first upper end portion 17d. In this way, the diameter of the first upper end portion 17d is smaller than that of the first contact plug 10.

In this case, the base portion 17c of the first heater electrode 17a may cover at least the entire upper end portion of the first contact plug 10 or may overlap the upper end portions of the titanium nitride film 15 and the titanium film 16. The center position of the first upper end portion 17d of the first heater electrode 17a may be aligned substantially to the center position of the upper end portion of the first contact plug 10. The second interlayer insulating film 12 and the fourth interlayer insulating film 14 are formed around the first heater electrode 17a so that the second interlayer insulating film 12 and the fourth interlayer insulating film 14 cover the side surface of the first heater electrode 17a and the upper surface of the semiconductor substrate 1.

The second heater electrode 17b may have a substantially rod shape. The second heater electrode 17b may be bonded to the first upper end portion 17d of the first heater electrode 17a. In this way, the heater electrode 17 may have a tapered shape. The heater electrode 17 is tapered to it top. The tapering rate decreases as the position moves from the bottom portion to the top portion. The first heater electrode 17a contacts the first contact plug 10. The first heater electrode 17a is higher in tapering rate than the second heater electrode 17b.

The fourth interlayer insulating film 14 is formed around the second heater electrode 17b so that the fourth interlayer insulating film 14 covers the side surface of the second heater electrode 17b and the upper surface of the second interlayer insulating film 12. A second upper end portion 17e of the second heater electrode 17b may be exposed from the fourth interlayer insulating film 14. The second upper end portion 17e may be connected to a phase-change recording layer 20, which will be described below.

### Phase-Change Recording Layer 20:

The phase-change recording layer 20 may be made of a material including at least two of germanium (Ge), antimony (Sb), tellurium (Te), selenium (Se), gallium (Ga), and indium (In). For example, the phase-change recording layer 20 may be made of gallium antimonide (GaSb), indium antimonide (InSb), indium selenide (InSe), antimony telluride (Sb₂Te₃), germanium telluride (GeTe), Ge₂Sb₂Te₅, InSbTe, GaSeTe, SnSb₂Te₄, or InSbGe and is connected to the second upper end portion 17e of the second heater electrode 17b. The phase-change recording layer 20 contacts the top portion of the heater electrode 17. The phase-change recording layer 20 contacts the second heater electrode 17b of the heater electrode 17. A top contact area between the top portion and the phase change recording layer is smaller than a bottom contact area between the bottom portion and the first contact plug.

### Upper Electrode 21:

The upper electrode 21 is a conductor film which may be made of, for example, tungsten (W) or aluminum (Al) and is formed so as to cover the phase-change recording layer 20.

The upper electrode 21 is connected to a bit line (not shown). Application of a voltage to the upper electrode 21 cases a current flow through the upper electrode 21, the phase-change recording layer 20, the heater electrode 17, and the first contact plug 10 in this order and then the current flow to the ground line 5 through the MOS transistor 30. In this way, when a current flows to the heater electrode 17, the heater electrode 17 generates heat and the phase of the phase-change recording layer 20 connected to the second upper end portion 17e is changed. A region of the phase-change recording layer 20 in which a phase change occurs is referred to as a phase-change recording region 20a.

The heater electrode 17 may be made of, for example, tungsten (W) and the heater electrode 17 is surrounded by a third side wall made of a silicon nitride (SiN). In addition, the third side wall is surrounded by the second interlayer insulating film. The phase-change recording layer 20 and the upper electrode 21 are formed in this order on the heater electrode 17 and the second interlayer insulating film. The upper electrode 21 is connected to the bit line (not shown) and is electrically connected to the ground line 5, which will be described below.

### Ground Line 5:

A second contact plug 4 is formed on the second diffusion layer 3 and the ground line 5 is formed on the second contact plug 4. The ground line 5 is surrounded by the first interlayer insulating film 11. In this way, the ground line 5 is connected to the second diffusion layer 3 through the second contact plug 4.

In the phase-change memory device 50 according to this embodiment of the invention, the upper end portion (second upper end portion 17e) of the heater electrode 17 may have a tapered shape. Therefore, it is possible to reduce the contact area between the heater electrode 17 and the phase-change recording layer 20. As a result, it is possible to reduce the area of the phase-change region 20a and effectively heat (change the phase of) the phase-change recording layer 20. In addition, it is possible to reliably change the phase of the phase-change recording layer 20 and thus obtain a small and high-precision phase-change memory device 50. Further, it is possible to reduce the area of the phase-change region 20a and thus reduce electricity consumption. Therefore, it is easy to control the amount of current and it is possible to reduce power consumption.

Since the fourth interlayer insulating film 14 covers the side surface of the heater electrode 17, it is possible to prevent the diffusion of heat from the heater electrode 17 and effectively heat the phase-change recording layer 20. Therefore, a defect is less likely to occur in the heater electrode or the side wall and it is possible to obtain the phase-change memory device 50 with high durability. In addition, since no side wall is formed around the heater electrode 17, it is possible to simplify the structure of the storage element unit 31.

Since the generation of heat from the heater electrode 17 and the diffusion of heat are prevented, a defect is less likely to occur in the heater electrode 17 and the periphery thereof and it is possible to improve the durability of the phase-change memory device 50. According to these features, it is possible to increase the degree of integration (capacity) of the phase-change memory device 50, to reduce power consumption, and to improve the durability.

A method of manufacturing the phase-change memory device 50 according to this embodiment of the invention will be described with reference to the drawings. In the drawings used in the following description, in some cases, for ease of understanding of characteristics, characteristic portions are enlarged, and a scale of each component is appropriately changed in order to have a recognizable size. For example, materials and dimensions exemplified in the following description are just illustrative, and the invention is not necessarily limited thereto. Various modifications of the invention can be made without departing from the scope and spirit of the invention.

A method of manufacturing a phase-change memory device including the phase-change memory device 50 according to this embodiment of the invention may include the following processes. The MOS transistor 30 and the ground line 5 are formed. The first contact plug 10 is formed. The second interlayer insulating film 12 is formed. A first opening portion 22 is formed. A first heater electrode portion 27a is formed. The third interlayer insulating film 13 is formed. A second heater electrode portion 27b and a monitoring pattern 27c are formed. A hard mask 23 is formed. The third interlayer insulating film 13 is removed. The heater electrode 17 is formed. The fourth interlayer insulating film 14 is formed. The phase-change recording layer 20 and the upper electrode 21 are formed. Each of the processes will be described in detail.

Process of Forming MOS Transistor 30 and Ground line 5:

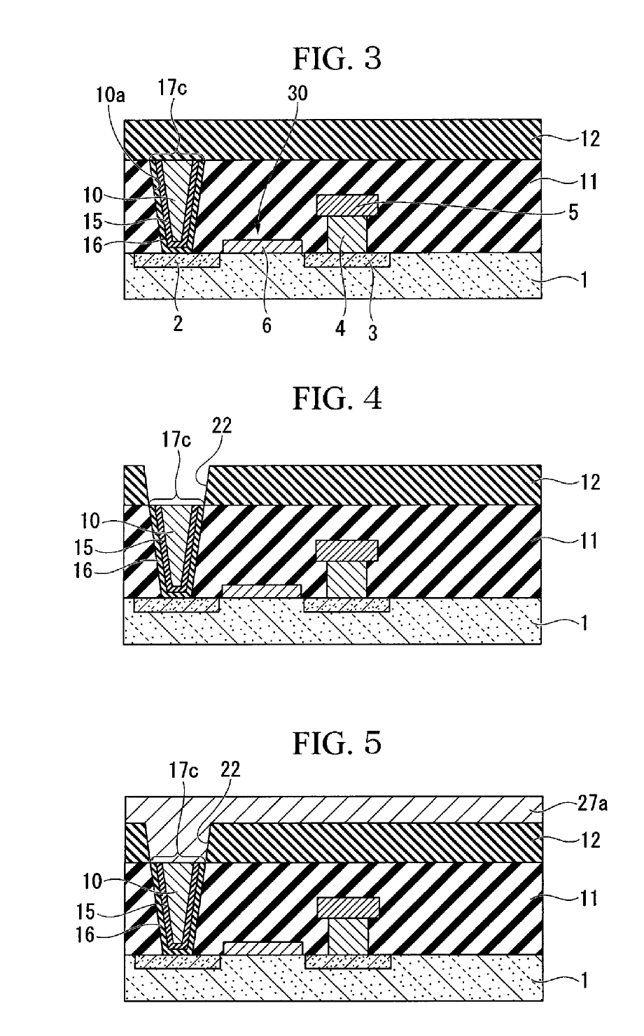

As shown in FIG. 3, the MOS transistor 30 and the ground line 5 are formed. The gate electrode 6 is formed on one surface of the semiconductor substrate 1 made of silicon. The gate electrode 6 includes a polycrystalline silicon film including N-type impurities, such as phosphorus, and a metal film made of tungsten, tungsten nitride, or tungsten silicide.

Then, the first diffusion layer 2 and the second diffusion layer 3 are formed in a region of the surface of the semiconductor substrate 1 that is not covered with the gate electrode 6 by, for example, an ion implantation method. In this way, each of the first diffusion layer 2 and the second diffusion layer 3 performs the functions as a source region or a drain region of the MOS transistor 30.

Then, the second contact plug 4 and the ground line 5 are formed on the second diffusion layer 3. After the MOS transistor 30 and the ground line 5 are formed, the first interlayer insulating film 11 is formed so that the first interlayer insulating film 11 covers the upper surface of the semiconductor substrate 1. In this case, the first interlayer insulating film 11 may have a thickness such that the MOS transistor 30 and the ground line 5 are not exposed.

### Process of Forming First Contact Plug 10:

Then, the first contact plug 10 is formed. First, a first opening portion 10a penetrating the first interlayer insulating film 11 is formed such that the surface of the first diffusion layer 2 is exposed. Then, the titanium film 16 and the titanium nitride film 15 are formed in this order so that the titanium film 16 and the titanium nitride film 15 cover the inner wall of the first opening portion 10a and the exposed portion of the first diffusion layer 2.

Then, a barrier film, such as a TiN/Ti film, or a conductive film, such as a tungsten (W) film, is deposited so as to fill up the inside of the titanium nitride film 15 in the first opening portion 10a. A polishing process is performed by a CMP (Chemical Mechanical Polishing) method until the first interlayer insulating film 11 is exposed. In this way, the first contact plug 10 is formed.

### Process of Forming Second Interlayer Insulating Film 12:

As shown in FIG. 3, the second interlayer insulating film 12 made of, for example, a silicon oxide is formed with a thickness of, for example, 60 nm so as to cover the first interlayer insulating film 11.

### Process of Forming Opening Portion (First Opening Portion 22):

As shown in FIG. 4, an opening portion (first opening portion 22) is formed.

First, the first opening portion 22 penetrating the second interlayer insulating film 12 is formed such that the upper end of the first contact plug 10 is exposed. In this case, it is preferable that the base portion 17c of the first opening portion 22 be formed such that the entire upper surface of the first contact plug 10 is exposed. The base portion 17c does not overlap the outside of the upper end of the titanium film 16.

### Process of Forming First Heater Electrode Portion 27a:

As shown in FIG. 5, the first heater electrode portion 27a is formed.

First, a conductive film made of a high-resistance material is formed so as to fill up the first opening portion 22 and cover the second interlayer insulating film 12. Typical examples of high-resistance material may include, but are not limited to, TiN (titanium nitride), TiSiN (titanium silicon nitride), TiAlN (titanium aluminum nitride), C (carbon), CN (carbon nitride), MoN (molybdenum nitride), TaN (tantalum nitride), PtIr (platinum-iridium), TiCN (titanium carbon nitride), and TiSiC (titanium silicon carbon).

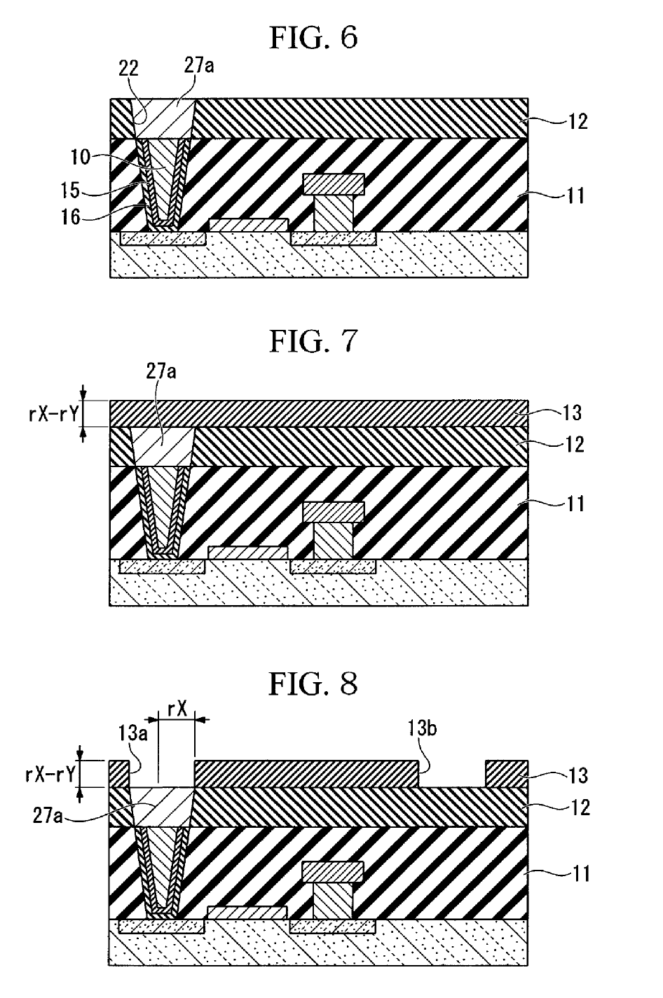

Then, a polishing process is performed by the CMP (Chemical Mechanical Polishing) method until the second interlayer insulating film 12 is exposed. In this way, the first heater electrode portion 27a is formed. In this case, the diameter of the upper end portion of the first heater electrode portion 27a is more than that of the base portion 17c of the first heater electrode portion 27a. FIG. 6 shows the formed first heater electrode portion 27a.

### Process of Forming Third Interlayer Insulating Film 13:

As shown in FIG. 7, for example, the third interlayer insulating film 13 made of a silicon oxide is formed so as to cover the second interlayer insulating film 12. In this case, the thickness of the third interlayer insulating film 13 is a value (rX-rY). The value (rX-rY) is obtained by subtracting the radius (rY) of the second upper end portion 17e from the radius (rX) of the second heater electrode portion 27b to be formed in the process, which will be described below. The value is equal to a desired etching depth in the process of etching the second heater electrode portion 27, which will be described below. In this embodiment, the thickness of the third interlayer insulating film 13 is, for example, 40 nm

In this case, it is preferable that the third interlayer insulating film 13 is thinner than the second interlayer insulating film 12 in order to prevent the side wall of the first heater electrode 17a from being completely etched in the process of forming the heater electrode 17, which will be described below.

### Process of Forming Second Heater Electrode Portion 27b and Monitoring Pattern 27c:

Then, the second heater electrode portion 27b and the monitoring pattern 27c are formed.

As shown in FIG. 8, a second opening portion 13a penetrating the third interlayer insulating film 13 is formed such that the first heater electrode portion 27a is exposed. In this case, it is preferable that the second opening portion 13a is formed such that the entire upper surface of the first heater electrode portion 27a is exposed. The second opening portion 13a is formed in order to accurately detect the end point of isotropic etching process. The isotropic etching process is performed on the first heater electrode portion 27a and the second heater electrode portion 27b in the process of forming the heater electrode 17, which will be described below. The center position of the second opening portion 13a is aligned substantially to the center position of the first contact plug 10. The alignment is made in order to prevent an unstable connection. The unstable connection is due to the deviation between the center position of the second heater electrode 17b and the center position of the first contact plug 10 in the process of forming the heater electrode 17, which will be described below.

At the same time as the second opening portion 13a is formed, a third opening portion 13b penetrating the third interlayer insulating film 13 is formed away from the second opening portion 13a. In this case, the radius of the third opening portion 13b is more than the depth (rX-rY) of the third opening portion 13b in order to accurately detect the end point of plasma etching performed on the first heater electrode portion 27a and the second heater electrode portion 27b in the process of forming the heater electrode 17, which will be described below.

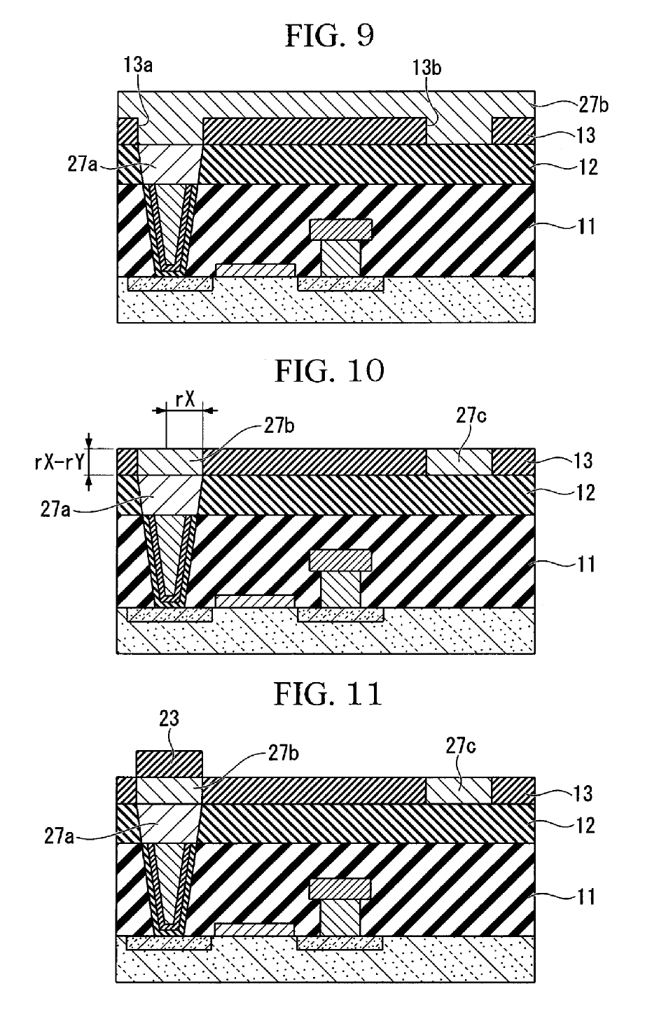

As shown in FIG. 9, a conductive film made of a high-resistance material is formed so as to fill up the second opening portion 13a and the third opening portion 13b and cover the third interlayer insulating film 13. Typical examples of the high-resistance material may include, but are not limited to, TiN (titanium nitride), TiSiN (titanium silicon nitride), TiA1N (titanium aluminum nitride), C (carbon), CN (carbon nitride), MoN (molybdenum nitride), TaN (tantalum nitride), PtIr (platinum-iridium), TiCN (titanium carbon nitride), and TiSiC (titanium silicon carbon).

As shown in FIG. 10, a polishing process is performed by the CMP (Chemical Mechanical Polishing) method until the third interlayer insulating film 13 is exposed. In this way, the second heater electrode portion 27b with a radius of rX and a thickness of rX-rY and the monitoring pattern 27c with a radius of rX-rY or more and a thickness of rX-rY are formed. The monitoring pattern 27c is used to detect the end point of plasma etching performed on the first heater electrode portion 27a and the second heater electrode portion 27b in the process of forming the heater electrode 17, which will be described below.

### Process of Forming Hard Mask 23:

As shown in FIG. 11, a hard mask 23 for forming the heater electrode 17 is formed on the second heater electrode portion 27b by a photolithography method. In this case, it is preferable that the hard mask 23 is formed so that the hard mask 23 covers the entire upper surface of the second heater electrode portion 27b in order to accurately detect the end point of isotropic etching process. The isotropic etching process is performed on the monitoring pattern 27c in the process of forming the heater electrode 17, which will be described below.

### Process of Removing Third Interlayer Insulating Film 13:

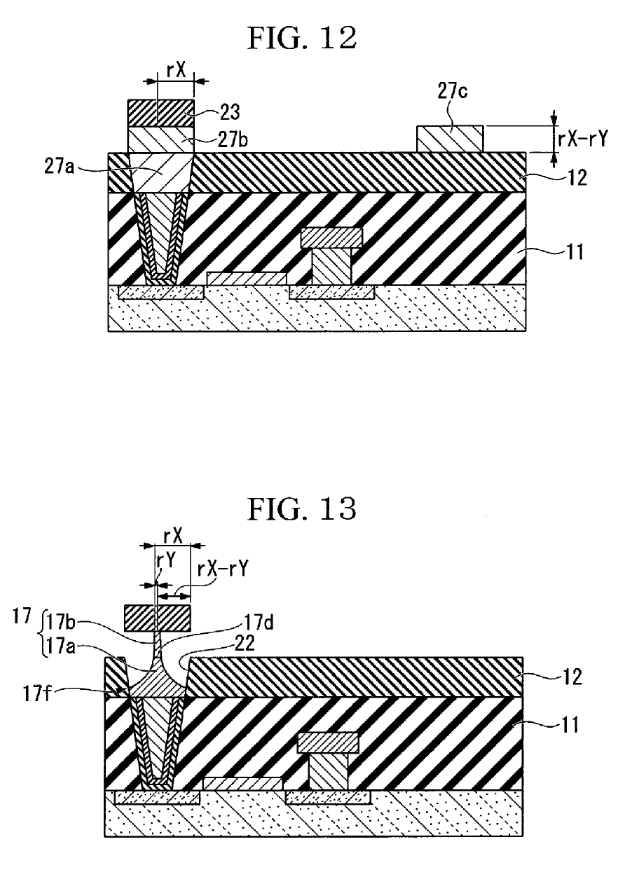

As shown in FIG. 12, the third interlayer insulating film 13 may be removed by, for example, a dry etching method. In this way, the side surface of the second heater electrode portion 27b and the monitoring pattern 27c are exposed.

### Process of Forming Heater Electrode 17:

Then, the heater electrode 17 is formed. As shown in FIG. 13, isotropic etching (high-selectivity isotropic etching) is performed on the second heater electrode portion 27b and the monitoring pattern 27c. In this case, the monitoring pattern 27c is etched from the side surface and the upper surface. The radius of the monitoring pattern 27c is more than the thickness thereof. Therefore, the monitoring pattern 27c is etched to a depth corresponding to the thickness (rX-rY) and is completely removed.

In this case, since the upper end portion of the second heater electrode portion 27b is covered with the hard mask 23, the second heater electrode portion 27b is etched from only the side surface. When the second heater electrode portion 27b is etched, the upper end portion of the first heater electrode portion 27a is gradually exposed from the outside thereof and is then etched. In this way, the first heater electrode portion 27a has a tapered shape toward the upper end portion 17d and the second heater electrode portion 27b has a substantially rod shape. In this way, the heater electrode 17 including the first heater electrode 17a and the second heater electrode 17b is formed.

In this case, since the time when the monitoring pattern 27c is completely etched is used as an etching end time, it is possible to etch the side surface of the second heater electrode portion 27b by a value corresponding to the thickness (rX-rY) of the monitoring pattern 27c. In this way, it is possible to form the heater electrode 17 in which the radius of the upper end portion (second upper end portion 17e) is rY.

In this case, for example, when the radius of the second heater electrode portion 27b is 50 nm and the desired radius of the second upper end portion 17e is 10 nm, the second interlayer insulating film 12 may be formed with a thickness of 60 nm and the third interlayer insulating film 13 may be formed with a thickness of 40 nm In this way, the first heater electrode portion 27a is formed with a thickness of 60 nm and the monitoring pattern 27c is formed with a thickness of 40 nm.

In this case, the thickness of the second interlayer insulating film 12 does not have an effect on the radius of the second upper end portion 17e, but it is preferable that the thickness of the second interlayer insulating film 12 be more than the radius of the second heater electrode portion 27b. The reason is that, when the side surface of the second heater electrode portion 27b is etched, the first heater electrode portion 27a is also etched from the upper end and the first heater electrode portion 27a is removed up to the side portion 17f.

Since the time when the monitoring pattern 27c is completely etched is used as an etching end time, the second heater electrode portion 27b is removed 40 nm from the outside and then etching ends. In this way, it is possible to form the heater electrode 17 in which the radius of the upper end portion (second upper end portion 17e) is 10 nm

As such, it is possible to form the second upper end portion 17e with a desired radius (rY) by forming the monitoring pattern 27c with a thickness (rX-rY) corresponding to the radius (rX) of the second heater electrode portion 27b.

In addition, the radius (rY) of the second upper end portion 17e may be adjusted by a composition of the detection of the end point by the monitoring pattern 27c and the measurement of the etching time.

### Process of Forming Fourth Interlayer Insulating Film 14:

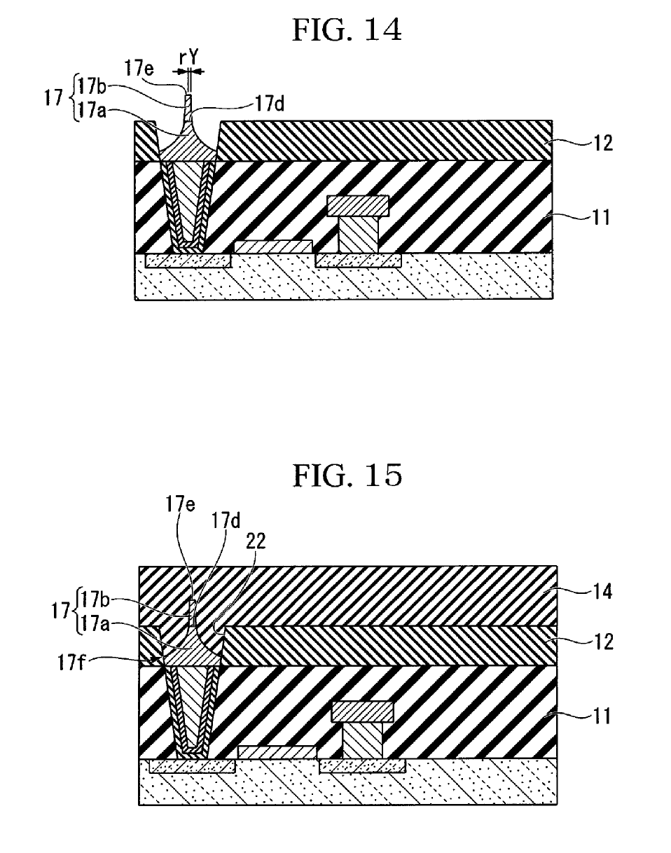

As shown in FIG. 14, the hard mask 23 is removed to expose the second upper end portion 17e.

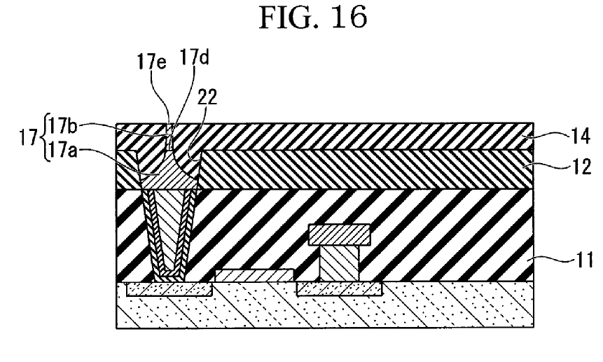

As shown in FIG. 15, the fourth interlayer insulating film 14 made of, for example, a silicon oxide is formed so as to fill up the first opening portion 22 and cover the third interlayer insulating film 13.

As shown in FIG. 16, a polishing process is performed by the CMP method until the upper end portion (second upper end portion 17e) of the heater electrode 17 is exposed.

### Process of Forming Phase-Change Recording Layer 20 and Upper Electrode 21:

As shown in FIG. 2, the phase-change recording layer 20 is formed so that the phase-change recording layer 20 covers the fourth interlayer insulating film 14. It is preferable that the phase-change recording layer 20 is made of a material including at least two of germanium (Ge), antimony (Sb), tellurium (Te), selenium (Se), gallium (Ga), and indium (In). For example, the phase-change recording layer 20 may be made of gallium antimonide (GaSb), indium antimonide (InSb), indium selenide (InSe), antimony telluride (Sb₂Te₃), germanium telluride (GeTe), Ge₂Sb₂Te₅, InSbTe, GaSeTe, SnSb₂Te₄, or InSbGe. When these materials are used, it is possible to stably perform a phase change and maintain the phase-changed state.

Then, the upper electrode 11, which is a conductor film made of, for example, tungsten (W) or aluminum (Al), is formed on the phase-change recording layer 20.

The phase-change memory device 50 shown in FIG. 2 is manufactured by the above-mentioned processes.

In the method of manufacturing the phase-change memory device according to this embodiment of the invention, the monitoring pattern 27c is formed with a thickness (rX-rY) corresponding to the radius (rX) of the second heater electrode portion 27b, according to the desired radius (rX) of the second heater electrode portion 27b. Therefore, it is possible to form the second upper end portion 17e with a desired radius (rY). As a result, it is possible to easily adjust the contact area between the phase-change recording layer 20 and the upper end portion (second upper end portion 17e) of the heater electrode 17.

Since the heater electrode 17 is formed by etching, it is possible to accurately form the upper parts (second heater electrode portions 27b) of a plurality of heater electrodes 17 with the same diameter. Therefore, it is possible to uniformly heat the phase-change recording layer 20 with each of the heater electrodes 17.

Since the entire upper surface of the first contact plug 10 can be covered with the base portion of the heater electrode 17, it is possible to reduce current loss. Therefore, it is possible to accurately form the phase-change memory device 50.

Since the heater electrode 17 is formed by isotropic etching, it is not necessary to form a side wall (third side wall 118) around the heater electrode 17. Therefore, it is not necessary to stack the heater electrode portions and it is possible to reduce the height of the heater electrode 17. As a result, it is possible to reduce the size of the phase-change memory device 50 and manufacture a small and high-capacity phase-change memory device 50.

Since it is possible to reduce the contact area between the phase-change recording layer 20 and the upper end portion (second upper end portion 17e) of the heater electrode 17, it is possible to apply high-density power to the phase-change recording region 20a with low power. As a result, it is possible to effectively heat (change the phase of) the phase-change recording layer 20 and reliably perform a phase change from the phase-change recording layer 20 to the change recording region 20a with a small amount of current.

Since the amount of current is reduced, the generation of heat is also reduced. Therefore, a defect is less likely to occur due to heat and it is possible to obtain the phase-change memory device 50 with high durability. In this way, according to the above-described embodiment of the invention, it is possible to increase the degree of integration (capacity) of the phase-change memory device 50, reduce power consumption, and improve durability.

The embodiments of the invention relates to the phase-change memory 50 (PRAM). But the embodiments of the invention can be used in the semiconductor industry requiring high-capacity and low-power memories.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
forming a heater electrode film in a first inter-layer insulating film over a semiconductor substrate;
forming a mask over the heater electrode film;
selectively removing the first inter-layer insulating film using the mask to expose a side surface of an upper portion of the heater electrode film;
subjecting the exposed side surface of the heater electrode film to an anisotropic etching process using the mask, to selectively remove the heater electrode film to form a heater electrode which is tapered to its top;
removing the mask; and
forming a phase change recording layer which contacts the top of the heater electrode.

2. The method according to claim 1, further comprising:
forming an upper electrode on the phase change recording layer.

3. The method according to claim 2, further comprising:
forming a second inter-layer insulating film which covers the heater electrode after removing the mask and before forming the phase change recording layer on the second inter-layer insulating film.

4. The method according to claim 2, wherein forming the heater electrode film in the first inter-layer insulating film comprises:
forming a first insulating layer over the substrate;
forming a first opening in the first insulating layer;
forming a first heater electrode layer in the first hole;
forming a second insulating layer on the first insulating layer and the first heater electrode layer;
forming a second opening in the second insulating layer, the second opening being positioned over the first heater electrode layer; and
forming a second heater electrode layer in the second hole, the second heater electrode layer being on the first heater electrode layer, the first and second heater electrode layers forming the heater electrode film, the first and second insulating layers forming the first inter-layer insulating film.

5. The method according to claim 4, wherein forming the mask over the heater electrode film comprises:
forming the mask on the second heater electrode layer.

6. The method according to claim 5, wherein selectively removing the first inter-layer insulating film comprises:
removing the second heater electrode layer to expose the side surface of the second heater electrode layer.

7. The method according to claim 6, wherein subjecting the exposed side surface of the heater electrode film comprises:
subjecting the exposed side surface of the second heater electrode layer to the anisotropic etching process using the mask, to isotropically etch the first and second heater electrode layers.

8. The method according to claim 2, wherein forming the heater electrode film in the first inter-layer insulating film comprises:
forming a first inter-layer insulating layer over the substrate;
forming a first opening in the first inter-layer insulating layer;
forming a first heater electrode layer in the first hole;
forming a second inter-layer insulating layer on the first inter-layer insulating layer and the first heater electrode layer;
forming second and third openings in the second inter-layer insulating layer, the second opening being positioned over the first heater electrode layer; and
forming a second heater electrode layer and a monitor pattern in the second and third holes resistively, the second heater electrode layer being on the first heater electrode layer, the first and second heater electrode layers forming the heater electrode film, the first and second inter-layer insulating layers forming the first inter-layer insulating film.

9. The method according to claim 8, wherein forming the mask over the heater electrode film comprises:
forming the mask on the second heater electrode layer.

10. The method according to claim 9, wherein selectively removing the inter-layer insulating film comprises:
removing the second heater electrode layer to expose the monitor pattern and the side surface of the second heater electrode layer.

11. The method according to claim 10, wherein subjecting the exposed side surface of the heater electrode film comprises:
subjecting the monitor pattern and the exposed side surface of the second heater electrode layer to the anisotropic etching process using the mask, to isotropically etch the first and second heater electrode layers and the monitor pattern,
wherein the anisotropic etching process is terminated when the monitor pattern is completely removed.

12. The method according to claim 11, wherein the first and second heater electrode layers are isotropically etched by an etching amount that corresponds to the thickness of the monitor pattern, provided that the monitor pattern has a horizontal size that is greater than the thickness of the monitor pattern.

13. The method according to claim 1, further comprising:
forming a contact plug in a third inter-layer insulating film over the semiconductor substrate, before forming the heater electrode over the contact plug and in the first inter-layer insulating film.

14. A method of forming a semiconductor device, the method comprising:
forming a heater electrode film and a monitoring pattern in a first inter-layer insulating film over a semiconductor substrate;
forming a mask that covers the heater electrode film without covering the monitoring pattern;
selectively removing the first inter-layer insulating film using the mask to expose the monitoring pattern and a side surface of an upper portion of the heater electrode film;
subjecting the monitoring pattern and the exposed side surface of the heater electrode film to an anisotropic etching process using the mask, to selectively remove the heater electrode film until the monitoring pattern is completely removed, to form a heater electrode which is tapered to its top;
removing the mask; and
forming a phase change recording layer which contacts the top of the heater electrode.

15. The method according to claim 14, further comprising:
forming an upper electrode on the phase change recording layer; and
forming a second inter-layer insulating film which covers the heater electrode after removing the mask and before forming the phase change recording layer on the second inter-layer insulating film.

16. The method according to claim 15, wherein forming the heater electrode film in the first inter-layer insulating film comprises:
forming a first insulating layer over the substrate;
forming a first opening in the first insulating layer;
forming a first heater electrode layer in the first hole;
forming a second insulating layer on the first insulating layer and the first heater electrode layer;
forming a second opening in the second insulating layer, the second opening being positioned over the first heater electrode layer; and
forming a second heater electrode layer in the second hole, the second heater electrode layer being on the first heater electrode layer, the first and second heater electrode layers forming the heater electrode film, the first and second insulating layers forming the first inter-layer insulating film, and
wherein selectively removing the first inter-layer insulating film comprises: removing the second heater electrode layer to expose the side surface of the second heater electrode layer.

17. The method according to claim 14, further comprising:
forming a contact plug in a third inter-layer insulating film over the semiconductor substrate, before forming the heater electrode over the contact plug and in the first inter-layer insulating film.

18. A method of forming a semiconductor device, the method comprising:
forming a first inter-layer insulating layer over a semiconductor substrate;
forming a first opening in the first inter-layer insulating layer;
forming a contact plug in the first opening;
forming a second inter-layer insulating layer over the contact plug and the first inter-layer insulating layer;
forming a second opening in the second insulating layer, the second opening being positioned over the contact plug;
forming a first heater electrode layer in the second hole;
forming a third insulating layer over the second insulating layer and the first heater electrode layer;
forming a third opening in the third insulating layer, the third opening being positioned over the first heater electrode layer;
forming a second heater electrode layer in the third hole, the second heater electrode layer being on the first heater electrode layer, the first and second heater electrode layers forming the heater electrode film;
forming a mask over the heater electrode film;
selectively removing the third inter-layer insulating film using the mask to expose the side surface of the second heater electrode layer;
subjecting the exposed side surface of the heater electrode film to an anisotropic etching process using the mask, to selectively remove the heater electrode film to form a heater electrode which is tapered to its top;
removing the mask;
forming a fourth inter-layer insulating film which covers the heater electrode; and
forming a phase change recording layer over the fourth inter-layer insulating film, the phase change recording layer contacting the top of the heater electrode.

19. The method according to claim 18, further comprising:
forming an upper electrode on the phase change recording layer.

20. The method according to claim 18, further comprising:
forming a fourth opening in the third insulating layer; and
forming a monitor pattern in the fourth hole, and
wherein the anisotropic etching process is terminated when the monitor pattern is completely removed.
